(19) United States
(12) Patent Application Publication
(10) Pub. No.: US 2025/0386532 A1
(43) Pub. Date: Dec. 18, 2025

(54) SEMICONDUCTOR STRUCTURE AND MANUFACTURING METHOD THEREOF

(71) Applicant: UNITED MICROELECTRONICS CORP., Hsin-Chu City (TW)

(72) Inventors: Chang-Yih Chen, Tainan City (TW); Yi-Wen Chen, Chiayi County (TW); Kuo-Hsing Lee, Hsinchu County (TW); Chun-Hsien Lin, Tainan City (TW)

(73) Assignee: UNITED MICROELECTRONICS CORP., Hsin-Chu City (TW)

(21) Appl. No.: 18/780,521

(22) Filed: Jul. 23, 2024

(30) Foreign Application Priority Data
Jun. 12, 2024 (TW) 113121648

(51) Int. Cl. H01L 29/66; H01L 21/02; H01L 29/08; H01L 29/417; H01L 29/78

(52) U.S. Cl. CPC H10D 30/024; H01L 21/02164; H01L 21/02178; H01L 21/02236; H01L 21/0228; H01L 21/02532; H10D 30/6211; H10D 30/6219; H10D 62/151

(57) ABSTRACT

A manufacturing method of a semiconductor structure includes the following steps. A semiconductor substrate is provided, and the semiconductor substrate includes a fin-shaped structure. A silicon germanium epitaxial structure is formed on the fin-shaped structure, a silicon cap layer is formed on the silicon germanium epitaxial structure, and an oxide cap layer is formed on the silicon cap layer. A semiconductor structure includes a semiconductor substrate, a silicon germanium epitaxial structure, an oxide cap layer, and a silicon-rich interfacial layer. The semiconductor substrate includes a fin-shaped structure, and the silicon germanium epitaxial structure is disposed on the fin-shaped structure. The oxide cap layer encompasses the silicon germanium epitaxial structure, and the silicon-rich interfacial layer is disposed between the silicon germanium epitaxial structure and the oxide cap layer.

### BACKGROUND OF THE INVENTION

### 1. Field of the Invention

The present invention relates to a semiconductor structure and a manufacturing method thereof, and more particularly, to a semiconductor structure including a silicon germanium epitaxial structure and a manufacturing method thereof.

### 2. Description of the Prior Art

As the size of the field effect transistors (FETs) becomes smaller continuously, the conventional planar field effect transistor has difficulty in development because of the manufacturing limitations. Therefore, for overcoming the manufacturing limitations, the non-planar transistor technology such as fin field effect transistor (FinFET) technology is developed to replace the planar FET and becomes a development trend in the related industries. Additionally, in integrated circuits, different types of transistors (such as the planar transistors and the non-planar transistors described above) have to be disposed in the integrated circuit for product requirements, and there are different transistor structures for different operation voltages also. In the embedded high voltage (eHV) process, transistor elements for different operation voltages (such as a high voltage transistor, a middle voltage transistor, and a low voltage transistor) may be disposed within one chip for the product specification, and the structures and manufacturing method of the transistors are partially different from one another. Therefore, how to improve the manufacturing process integration of the different transistor structures through structural design and/or process design for improving manufacturing yield and/or satisfying product specification is an ongoing research direction for people in related fields.

### SUMMARY OF THE INVENTION

A semiconductor structure and a manufacturing method thereof are provided in the present invention. A silicon cap layer is formed on a silicon germanium epitaxial structure, and a silicon-rich interfacial layer may be formed between an oxide cap layer and the silicon germanium epitaxial structure in a subsequent process of forming the oxide cap layer and/or after the oxide cap layer is formed for improving the protection to the silicon germanium epitaxial structure.

According to an embodiment of the present invention, a manufacturing method of a semiconductor structure is provided. The manufacturing method includes the following steps. A semiconductor substrate is provided, and the semiconductor substrate includes a fin-shaped structure. A silicon germanium epitaxial structure is formed on the fin-shaped structure. A silicon cap layer is formed on the silicon germanium epitaxial structure, and an oxide cap layer is formed on the silicon cap layer.

According to an embodiment of the present invention, a semiconductor structure is provided. The semiconductor structure includes a semiconductor substrate, a silicon germanium epitaxial structure, an oxide cap layer, and a silicon-rich interfacial layer. The semiconductor substrate includes a fin-shaped structure. The silicon germanium epitaxial structure is disposed on the fin-shaped structure. The oxide cap layer encompasses the silicon germanium epitaxial structure, and the silicon-rich interfacial layer is disposed between the silicon germanium epitaxial structure and the oxide cap layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are schematic drawings illustrating a manufacturing method of a semiconductor structure according to an embodiment of the present invention, wherein

FIG. 2 is a schematic drawing in a step subsequent to FIG. 1,

FIG. 3 is another cross-sectional schematic drawing illustrating the condition of FIG. 2,

FIG. 4 is a schematic drawing in a step subsequent to FIG. 2,

FIG. 5 is a schematic drawing illustrating influence of a silicon cap layer on a condition after an oxide cap layer is formed,

FIG. 6 is a schematic drawing in a step subsequent to FIG. 4,

FIG. 7 is a schematic drawing in a step subsequent to FIG. 6,

FIG. 8 is another cross-sectional schematic drawing illustrating the condition of FIG. 7, and

FIG. 9 is a flow chart of a part of the manufacturing method.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

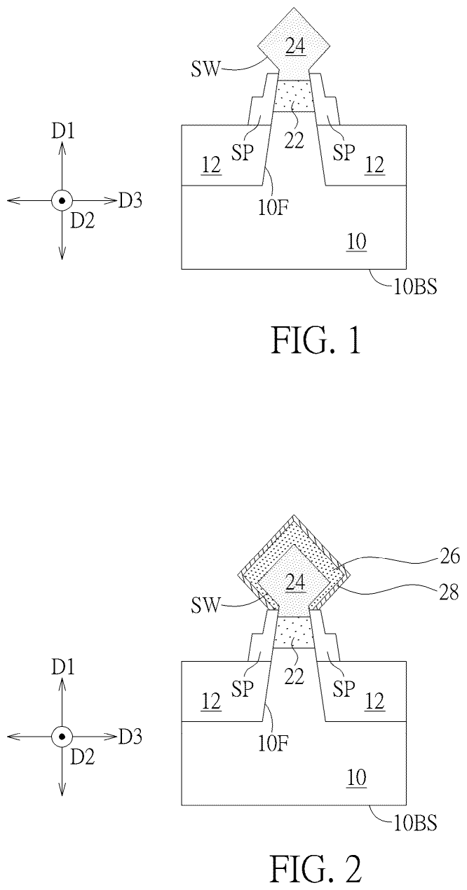

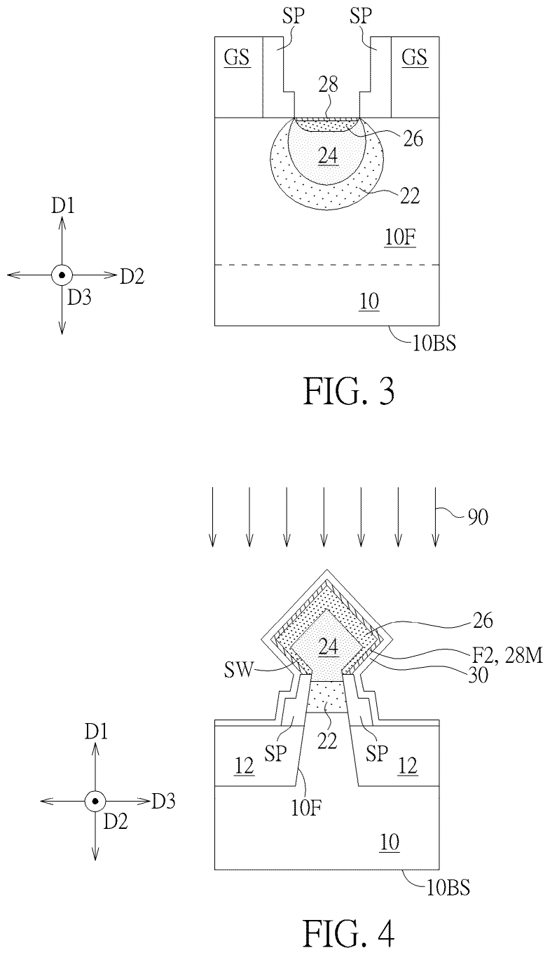

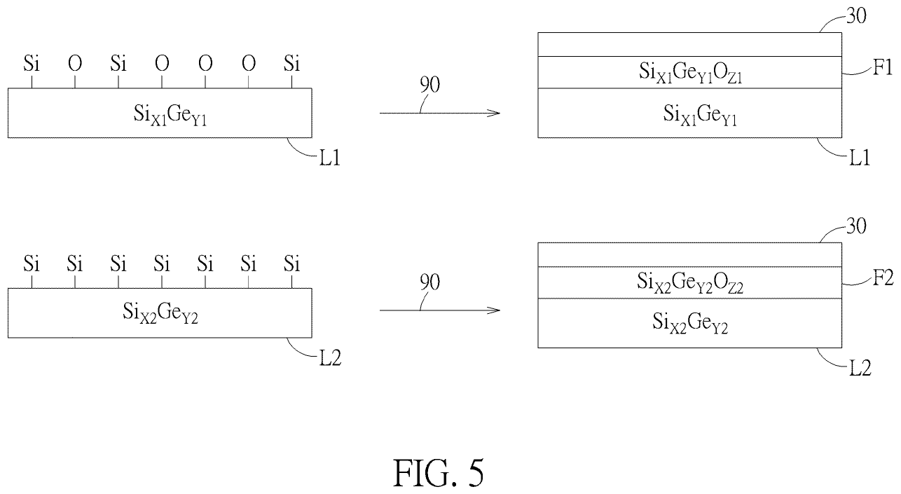

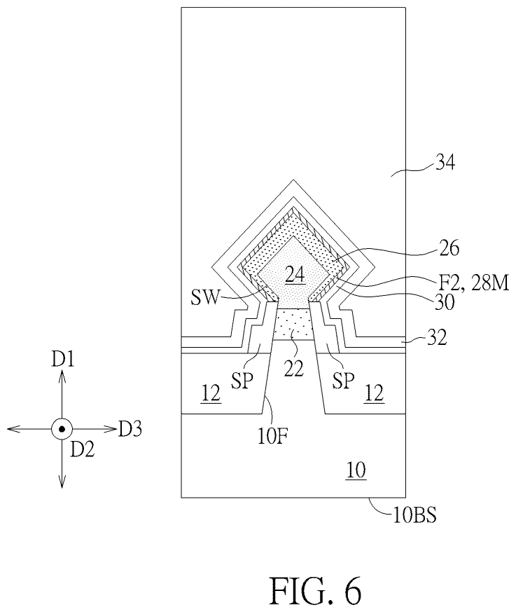

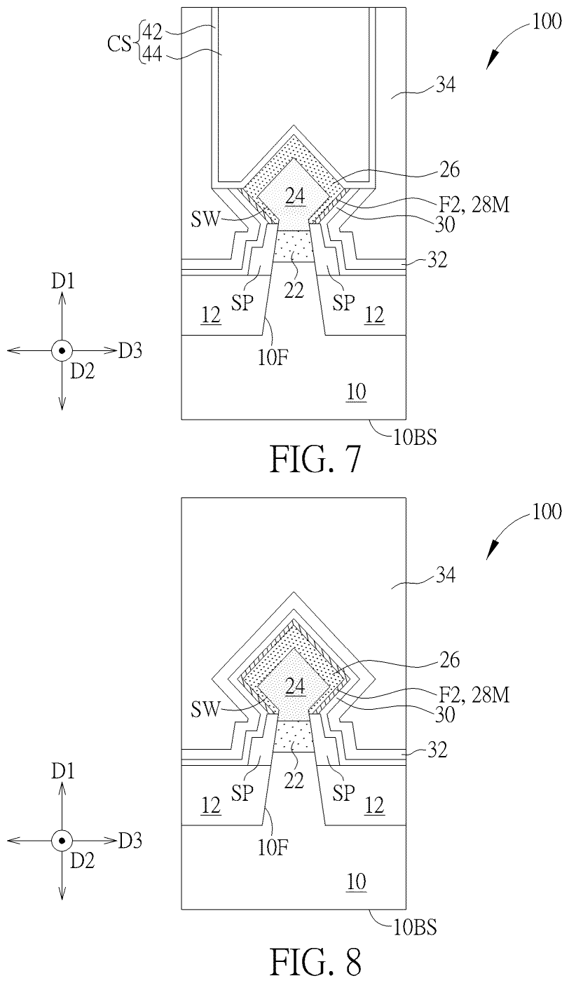

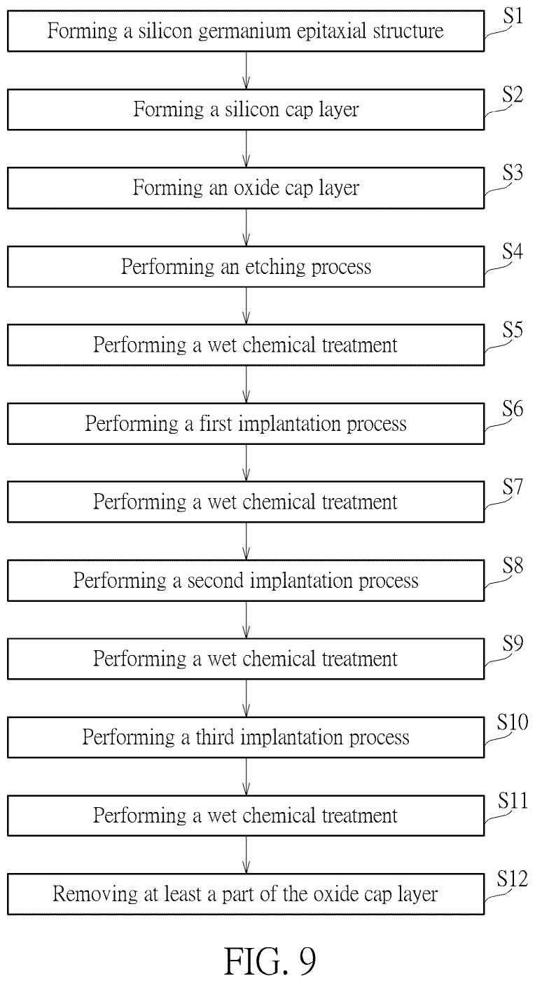

Please refer to FIGS. 1-9. FIGS. 1-9 are schematic drawings illustrating a manufacturing method of a semiconductor structure according to an embodiment of the present invention, wherein FIG. 2 is a schematic drawing in a step subsequent to FIG. 1, FIG. 3 is another cross-sectional schematic drawing illustrating the condition of FIG. 2, FIG. 4 is a schematic drawing in a step subsequent to FIG. 2, FIG. 5 is a schematic drawing illustrating influence of a silicon cap layer on a condition after an oxide cap layer is formed, FIG. 6 is a schematic drawing in a step subsequent to FIG. 4, FIG. 7 is a schematic drawing in a step subsequent to FIG. 6, FIG. 8 is another cross-sectional schematic drawing illustrating the condition of FIG. 7, and FIG. 9 is a flow chart of a part of the manufacturing method. A manufacturing method of a semiconductor structure is provided in this embodiment and includes the following steps. As shown in FIG. 1, a semiconductor substrate 10 is provided, the semiconductor substrate 10 includes a fin-shaped structure 10F, and a silicon germanium epitaxial structure 24 is formed on the fin-shaped structure 10F. Subsequently, as shown in FIG. 2 and FIG. 3, a silicon cap layer 28 is formed on the silicon germanium epitaxial structure 24. As shown in FIG. 2 and FIG. 4, an oxide cap layer 30 is then formed on the silicon cap layer 28. By forming the silicon cap layer 28 on the silicon germanium epitaxial structure 24, a silicon-rich interfacial layer (such as an interfacial layer F2, but not limited thereto) may be formed between the silicon germanium epitaxial structure 24 and the oxide cap layer 30 in the step of forming the oxide cap layer 30 and/or after the oxide cap layer 30 is formed for enhancing the effect of protecting the silicon germanium epitaxial structure 24.

In some embodiments, the semiconductor substrate 10 may include a silicon substrate, a silicon-on-insulator (SOI) substrate, or a substrate made of other suitable materials, the fin-shaped structure 10F may be formed by performing a patterning process to the semiconductor substrate 10, and the fin-shaped structure 10F may include the semiconductor material (such as silicon, but not limited thereto) in the semiconductor substrate 10 accordingly. In addition, the fin-shaped structure 10F may protrude upwards in a vertical direction D1 and extend in a horizontal direction (such as a horizontal direction D2, but not limited thereto). In some embodiments, the vertical direction D1 may be regarded as a thickness direction of the semiconductor substrate 10. The semiconductor substrate 10 may have a top surface and a bottom surface 10BS opposite to the top surface in the vertical direction D1, and the silicon germanium epitaxial structure 24, the silicon cap layer 28, and the oxide cap layer 30 may be formed at the side of the top surface. A horizontal direction substantially orthogonal to the vertical direction D1 (such as the horizontal direction D2, a horizontal direction D3, and other horizontal directions orthogonal to the vertical direction D1) may be substantially parallel with the bottom surface 10BS of the semiconductor substrate 10, but not limited thereto. In this description, a distance between the bottom surface 10BS of the semiconductor substrate 10 and a relatively higher location and/or a relatively higher part in the vertical direction D1 may be greater than a distance between the bottom surface 10BS of the semiconductor substrate 10 and a relatively lower location and/or a relatively lower part in the vertical direction D1. The bottom or a lower portion of each component may be closer to the bottom surface 10BS of the semiconductor substrate 10 in the vertical direction D1 than the top or upper portion of this component. Another component disposed above a specific component may be regarded as being relatively far from the bottom surface 10BS of the semiconductor substrate 10 in the vertical direction D1, and another component disposed under a specific component may be regarded as being relatively close to the bottom surface 10BS of the semiconductor substrate 10 in the vertical direction D1. It is worth noting that, in this description, a top surface of a specific component may include but is not limited to the topmost surface of this component in the vertical direction D1, and a bottom surface of a specific component may include but is not limited to the bottommost surface of this component in the vertical direction D1. Additionally, in this description, the condition that a certain component is disposed between two other components in a specific direction may include but is not limited to a condition that the certain component is sandwiched between the two other components in the specific direction.

Specifically, the manufacturing method in this embodiment may include but is not limited to the following steps. As shown in FIG. 1, in some embodiments, the manufacturing method may further include forming an isolation structure 12 and a spacer SP on the semiconductor substrate 10. The isolation structure 12 may surround a lower portion of the fin-shaped structure 10F in the horizontal direction, and the spacer SP may be partly formed on the isolation structure 12 and surround an upper portion of the fin-shaped structure 10F in the horizontal direction. The isolation structure 12 may include a single layer or multiple layers of insulation materials, such as an oxide insulation material or other suitable insulation materials, and the spacer SP may include a single layer or multiple layers of dielectric materials, such as silicon nitride or other suitable dielectric materials. In some embodiments, after the isolation structure 12 and the spacer SP are formed, a part of the fin-shaped structure 10F may be removed and the top surface of the fin-shaped structure 10F may be lower than the top surface of the spacer SP in the vertical direction D1 accordingly, but not limited thereto. Subsequently, as shown in FIG. 9 and FIG. 1, a step S1 may be carried out for forming the silicon germanium epitaxial structure 24 by a suitable approach (such as an epitaxial growth process, but not limited thereto). In some embodiments, a buffer layer 22 may be formed on the fin-shaped structure 10F by an epitaxial growth process first, and the silicon germanium epitaxial structure 24 may then be formed on the buffer layer 22, but not limited thereto. The buffer layer 22 may include silicon germanium or other suitable epitaxial structures, and an atomic percent of germanium in the buffer layer 22 may be lower than an atomic percent of germanium in the silicon germanium epitaxial structure 24 for reducing the lattice constant difference between the buffer layer 22 and the fin-shaped structure 10F and that contributes to defect reduction. For example, the atomic percent of germanium in the buffer layer 22 may substantially range from 25% to 35%, and the atomic percent of germanium in the silicon germanium epitaxial structure 24 may substantially range from 40% to 49%, but not limited thereto. Additionally, in the cross-sectional diagram of the silicon germanium epitaxial structure 24, the silicon germanium epitaxial structure 24 may include a portion extending outwards in the horizontal direction D3, and a sidewall SW of the silicon germanium epitaxial structure 24 may partially face diagonally upward and partially face diagonally downward.

As shown in FIG. 9 and FIG. 2, after the step of forming the silicon germanium epitaxial structure 24, a step S2 may be carried out for forming the silicon cap layer 28 on the silicon germanium epitaxial structure 24. In some embodiments, a silicon germanium cap layer 26 may be formed on the silicon germanium epitaxial structure 24 before the silicon cap layer 28 is formed, the silicon germanium cap layer 26 may encompass the exposed portion of the silicon germanium epitaxial structure 24, and the silicon germanium cap layer 26 and the silicon cap layer 28 may be formed by an epitaxial growth process or other suitable approaches. A part of the silicon germanium cap layer 26 and a part of the silicon cap layer 28 may be formed on the sidewall SW of the silicon germanium epitaxial structure 24, and because of the influence of the shape of the sidewall SW of the silicon germanium epitaxial structure 24, a part of the silicon germanium cap layer 26 and a part of the silicon cap layer 28 may be located under the sidewall SW of the silicon germanium epitaxial structure 24 in the vertical direction D1. In addition, an atomic percent of germanium in the silicon germanium cap layer 26 may be lower than the atomic percent of germanium in the silicon germanium epitaxial structure 24, and the atomic percent of germanium in the silicon germanium cap layer 26 may substantially range from 22% to 32%, for instance. The silicon cap layer 28 may consist of silicon substantially, and an atomic percent of silicon in the silicon cap layer 28 is higher than an atomic percent of silicon in the silicon germanium cap layer 26 accordingly. In addition, the silicon germanium cap layer 26 may directly contact the silicon germanium epitaxial structure 24, and a thickness of the silicon cap layer 28 may be less than a thickness of the silicon germanium cap layer 26. For example, the thickness of the silicon cap layer 28 may range from 10 angstroms to 15 angstroms, but not limited thereto. As shown in FIG. 2 and FIG. 3, in some embodiments, a plurality of gate structures GS may be formed on the semiconductor substrate 10 before the step of forming the buffer layer 22, each of the gate structures GS may be elongated in the horizontal direction D3 and disposed straddling the fin-shaped structure 10F, and the spacer SP may be partly formed on the sidewall of the gate structure GS. In some embodiments, the buffer layer 22, the silicon germanium epitaxial structure 24, the silicon germanium cap layer 26, and the silicon cap layer 28 may be located between two of the gate structures GS adjacent to each other in the horizontal direction D2. The buffer layer 22, the silicon germanium epitaxial structure 24, and the silicon germanium cap layer 26 may become a source/drain structure in a fin-type transistor structure by subsequence processes, the gate structure GS may be replaced with a metal gate and a gate dielectric layer of the fin-type transistor structure by the subsequence processes, and the gate structure GS may be regarded as a dummy gate structure accordingly, but not limited thereto.

As shown in FIG. 9, FIG. 2, and FIG. 4, after the step of forming the silicon cap layer 28, a step S3 may be carried out for forming the oxide cap layer 30 on the silicon cap layer 28. A part of the oxide cap layer 30 may be formed on the sidewall SW of the silicon germanium epitaxial structure 24, and because of the influence of the shape of the sidewall SW of the silicon germanium epitaxial structure 24, a part of the oxide cap layer 30 may be located under the sidewall SW of the silicon germanium epitaxial structure 24 in the vertical direction D1. In some embodiments, the oxide cap layer 30 may include an aluminum oxide layer or other suitable oxide material layer. The oxide cap layer 30 may be formed on the silicon cap layer 28, the spacer SP, and the isolation structure 12 by a deposition process 90, and the deposition process 90 may include an atomic layer deposition (ALD) process or other suitable deposition approaches. In some embodiments, at least a part of the silicon cap layer 28 may be oxidized to be silicon oxide in an interfacial layer (such as the interfacial layer F2, but not limited thereto) located between the oxide cap layer 30 and the silicon germanium epitaxial structure 24 by a process of forming the oxide cap layer 30 (such as the deposition process 90), and the interfacial layer F2 may include a silicon germanium oxide layer. The silicon in the interfacial layer F2 may include silicon coming from the silicon cap layer 28 and silicon coming from the silicon germanium cap layer 26, and the germanium in the interfacial layer F2 may come from the silicon germanium cap layer 26. After the oxide cap layer 30 is formed, the interfacial layer located between the oxide cap layer 30 and the silicon germanium cap layer 26 may include the interfacial layer F2 or a mixed interfacial layer 28M consisting of the interfacial layer F2 and the silicon cap layer 28. In other words, the silicon cap layer 28 may be completely oxidized by the deposition process 90 to become a portion of the interfacial layer F2 or only a part of the silicon cap layer 28 is oxidized by the deposition process 90 to become a portion of the interfacial layer F2, and the interfacial layer located between the oxide cap layer 30 and the silicon germanium cap layer 26 may be regarded as the mixed interfacial layer 28M consisting of the interfacial layer F2 and the silicon cap layer 28 when only a part of the silicon cap layer 28 is oxidized by the deposition process 90.

Please refer to FIG. 2, FIG. 4, and FIG. 5. FIG. 5 is a schematic drawing illustrating the influence of the silicon cap layer on the condition after the oxide cap layer is formed in some embodiments, the upper portion of FIG. 5 illustrates the conditions before and after the oxide cap layer is formed without forming the silicon cap layer, and the lower portion of FIG. 5 illustrates the conditions before and after the oxide cap layer is formed with the silicon cap layer. As shown in FIG. 5, FIG. 2, and FIG. 4, a cap layer L1 may be regarded as the silicon germanium cap layer 26 described above, and a cap layer L2 may be regarded as a composite layer composed of the silicon germanium cap layer 26 and the silicon cap layer 28 described above. The cap layer L1 may include a silicon germanium material with a chemical formula Si_{X1}Ge_{Y1}, the cap layer L2 may include a silicon germanium material with a chemical formula Si_{X2}Ge_{Y2}, X2 is greater than X1 and Y2 is less than Y1 because of the influence of the silicon cap layer 28, and more silicon atoms are located on the surface of the cap layer L2. In the condition without forming the silicon cap layer 28, an interfacial layer F1 may be formed between the cap layer L1 and the oxide cap layer 30 via the deposition process 90, and the interfacial layer F1 may include a silicon germanium oxide material with a chemical formula Si_{X1}Ge_{Y1}O_{Z1}. Relatively, in the condition with the silicon cap layer 28, the interfacial layer F2 may be formed between the cap layer L2 and the oxide cap layer 30 via the deposition process 90, and the interfacial layer F2 may include a silicon germanium oxide material with a chemical formula Si_{X2}Ge_{Y2}O_{Z2}. Because of the influence of the silicon cap layer 28, the ratio of silicon to oxygen in the interfacial layer F2 (such as X2/Z2) may be greater than the ratio of silicon to oxygen in the interfacial layer F1 (such as X1/Z1), and the interfacial layer F2 may be regarded as a silicon-rich interfacial layer for enhancing the effect of protecting the silicon germanium epitaxial structure 24 and the silicon germanium cap layer 26. In some embodiments, the atomic percent of silicon in the silicon cap layer 28 is higher than the atomic percent of silicon in the silicon germanium cap layer 26 before the oxide cap layer 30 is formed, the interfacial layer F2 may include a silicon germanium oxide layer after the oxide cap layer 30 is formed, and an atomic percent of silicon in this silicon germanium oxide layer may be higher than an atomic percent of germanium in this silicon germanium oxide layer. For example, an atomic percent of silicon in the interfacial layer F2 may be higher than 55%, and an atomic percent of germanium in the interfacial layer F2 may be lower than 45%, but not limited thereto.

As shown in FIG. 6, after the step of forming the oxide cap layer 30, an etching stop layer 32 may be formed on the oxide cap layer 30 and a dielectric layer 34 may be formed on the etching stop layer 32. The etching stop layer 32 may include nitrogen doped carbide (NDC, such as nitrogen doped silicon carbide), silicon nitride, silicon oxycarbide (SiOC), silicon oxycarbonitride (SiOCN), or other suitable dielectric materials, and the dielectric layer 34 may include silicon oxide, fluorosilicate glass (FSG), low dielectric constant (low-k) dielectric material, or other suitable dielectric materials. Subsequently, as shown in FIG. 7 and FIG. 9, a step S12 may be carried out for removing a least a part of the dielectric layer 34, a least a part of the etching stop layer 32, a least a part of the oxide cap layer 30, and a least a part of the interfacial layer F2, and a contact structure CS may be formed above the silicon germanium epitaxial structure 24 for forming a semiconductor structure 100. In other words, a part of the dielectric layer 34, a part of the etching stop layer 32, a part of the oxide cap layer 30, and a part of the interfacial layer F2 may be removed for forming a contact hole before the contact structure CS is formed, and the contact structure CS may be formed in the contact hole subsequently. The contact structure CS may be electrically connected with the silicon germanium epitaxial structure 24, and the silicon germanium cap layer 26 may be located between the contact structure CS and the silicon germanium epitaxial structure 24, but not limited thereto. In some embodiments, a metal silicide layer (not illustrated) may be formed on the silicon germanium cap layer 26 after the contact hole is formed and before the contact structure CS is formed for improving the connection between the contact structure CS and the silicon germanium cap layer 26, but not limited thereto. In addition, the contact structure CS may include a barrier layer 42 and an electrically conductive material 44 disposed on the barrier layer 42, the barrier layer 42 may include titanium nitride, tantalum nitride, or other suitable electrically conductive barrier materials, and the electrically conductive material 44 may include a material with relatively low electrical resistivity, such as copper, aluminum, tungsten, and so forth.

In some embodiments, a replacement metal gate (RMG) process may be carried out after the dielectric layer 34 is formed and before the contact structure CS is formed for replacing the dummy gate structure described above (such as the gate structure GS in FIG. 3) with a metal gate structure, and the thickness the dielectric layer 34 may be reduced by the related processes, but not limited thereto. Additionally, in some embodiments, the manufacturing method of the semiconductor structure 100 may be integrated with manufacturing methods of other semiconductor elements for forming semiconductor elements with different structures on different regions of the semiconductor substrate 10. For example, the manufacturing method of the semiconductor structure 100 may be a portion of an embedded high voltage (eHV) process, the manufacturing method of the semiconductor structure 100 may be used to form the source/drain structure in the fin-type transistor at least, and the fin-type transistor may include but is not limited to a low voltage transistor. In addition, the eHV process may also be used to form planar transistors and/or fin-type transistors with different structures on the semiconductor substrate 10, and these planar transistors and/or fin-type transistors may include transistor elements with different operation voltages, such as high voltage transistors, middle voltage transistors, and low voltage transistors. Therefore, after the oxide cap layer 30 described above is formed and before the step of removing a part of the oxide cap layer 30 for forming the contact structure CS, the silicon germanium epitaxial structure 24 and other regions on the semiconductor substrate 10 may have to go through many manufacturing steps together, and the silicon cap layer 28 and/or the interfacial layer F2 may be used to enhance the performance of protecting the silicon germanium epitaxial structure 24 and the silicon germanium cap layer 26 in these manufacturing steps. The manufacturing yield may be improved and/or the operation performance of the related semiconductor devices may be enhanced accordingly.

As shown in FIG. 9, in some embodiments, a plurality of other manufacturing steps (such as an etching process in a step S4 and implantation processes in a step S6, a step S8, and a step S10, but not limited thereto) and a plurality of corresponding wet chemical treatments (such as a step S5, a step S7, a step S9, and a step S11) may be performed to the semiconductor substrate after the oxide cap layer is formed (such as after the step S3) and before at least a part of the oxide cap layer is removed (such as before the step S12), and the silicon cap layer and/or the interfacial layer in the manufacturing method of this embodiment may be used to enhance the performance of protecting the silicon germanium epitaxial structure and the silicon germanium cap layer in these manufacturing steps and the wet chemical treatments. In some embodiments, the etching process and the implantation process described above may include a partially etching process using patterned photoresist as a mask and a partially implantation process using patterned photoresist as a mask, and the corresponding wet chemical treatments may include photoresist strip processes accordingly. For example, in the step S4 after the step S3, the etching process may be performed, the etching process may include but is not limited to an etching process for forming a spacer of a planar middle voltage transistor, and the corresponding wet chemical treatment (such as a photoresist strip process and a wet cleaning process) may be performed in the step S5 after this etching process. In the step S6 after the step S5, a first implantation process may be performed, the first implantation process may include but is not limited to an implantation process for forming source/drain electrodes in a fin-type transistor and a planar transistor, and the corresponding wet chemical treatment (such as a photoresist strip process and a wet cleaning process) may be performed in the step S7 after the first implantation process. In the step S8 after the step S7, a second implantation process may be performed, the second implantation process may include but is not limited to another implantation process for forming source/drain electrodes in the planar transistor, and the corresponding wet chemical treatment (such as a photoresist strip process and a wet cleaning process) may be performed in the step S9 after the second implantation process. In the step S10 after the step S9, a third implantation process may be performed, the third implantation process may include but is not limited to an implantation process for forming an electrostatic discharge protection device, and the corresponding wet chemical treatment (such as a photoresist strip process and a wet cleaning process) may be performed in the step S11 after the third implantation process.

In some embodiments, a photoresist stripper with oxidation effect may be used in the photoresist strip processes described above, and the wet cleaning processes described above may include a high temperature standard clean 1 (SC-1) process, a SPM cleaning processes, a diluted hydrofluoric acid cleaning process, or other suitable cleaning processes. The silicon germanium material tends to be oxidized by the photoresist stripper with oxidation effect for forming silicon germanium oxide, silicon germanium oxide tends to be attacked by the chemicals (such as a mixture of hydrogen-peroxide, ammonium-hydroxide, and deionized water) used in the higher temperature SC-1 process and the diluted hydrofluoric acid cleaning process and damage may occur accordingly. However, the etching rate of germanium oxide in the higher temperature SC-1 process and the diluted hydrofluoric acid cleaning process is higher than the etching rate of silicon oxide in the higher temperature SC-1 process and the diluted hydrofluoric acid cleaning process, and the silicon cap layer and the silicon-rich interfacial layer formed from the silicon cap layer described above (such as the interfacial layer F2 or the mixed interfacial layer 28M consisting the interfacial layer F2 and the silicon cap layer illustrated in FIG. 4) may be used to improve the performance of protecting the silicon germanium epitaxial structure and the silicon germanium cap layer accordingly for improving the manufacturing yield and/or enhancing the operation performance of the related semiconductor devices.

Please refer to FIG. 7 and FIG. 8. FIG. 7 may be regarded as a cross-sectional diagram of a portion of the silicon germanium epitaxial structure 24 in the semiconductor structure 100 with the contact structure CS formed thereon, and FIG. 8 be regarded as a cross-sectional diagram of another portion of the silicon germanium epitaxial structure 24 in the semiconductor structure 100 without the contact structure CS formed thereon. As shown in FIG. 7 and FIG. 8, the semiconductor structure 100 includes the semiconductor substrate 10, the silicon germanium epitaxial structure 24, the oxide cap layer 30, and the silicon-rich interfacial layer (such as the interfacial layer F2 or the mixed interfacial layer 28M consisting of the interfacial layer F2 and the silicon cap layer 28). The semiconductor substrate 10 includes the fin-shaped structure 10F. The silicon germanium epitaxial structure 24 is disposed on the fin-shaped structure 10F. The oxide cap layer 30 encompasses the silicon germanium epitaxial structure 24, and the silicon-rich interfacial layer is disposed between the silicon germanium epitaxial structure 24 and the oxide cap layer 30.

In some embodiments, the semiconductor structure 100 may further include the isolation structure 12, the spacer SP, the buffer layer 22, the silicon germanium cap layer 26, the etching stop layer 32, the dielectric layer 34, and the contact structure CS described above. The isolation structure 12 and the spacer SP are disposed above the semiconductor substrate 10, the isolation structure 12 may surround the lower portion of the fin-shaped structure 10F in the horizontal direction, and the spacer SP may be partly disposed on the isolation structure 12 and surround the upper portion of the fin-shaped structure 10F and the buffer layer 22 in the horizontal direction. The buffer layer 22 is disposed between the fin-shaped structure 10F and the silicon germanium epitaxial structure 24, the silicon germanium cap layer 26 may be disposed on the silicon germanium epitaxial structure 24, and the silicon germanium cap layer 26 may be partly disposed between the contact structure CS and the silicon germanium epitaxial structure 24 and partly disposed between the silicon-rich interfacial layer and the silicon germanium epitaxial structure 24. The etching stop layer 32 may be disposed on the oxide cap layer 30, and the dielectric layer 34 may be disposed on the etching stop layer 32. The contact structure CS may be disposed on the silicon germanium cap layer 26, the silicon germanium epitaxial structure 24, the silicon-rich interfacial layer, the oxide cap layer 30, and the etching stop layer 32. In some embodiments, a part of the silicon germanium cap layer 26, a part of the silicon-rich interfacial layer (such as the interfacial layer F2 or the mixed interfacial layer 28M), and a part of the oxide cap layer 30 may be located on the sidewall SW of the silicon germanium epitaxial structure 24, and because of the influence of the shape of the sidewall SW of the silicon germanium epitaxial structure 24, a part of the silicon germanium cap layer 26, a part of the silicon-rich interfacial layer, and a part of the oxide cap layer 30 may be located under the sidewall SW of the silicon germanium epitaxial structure 24 in the vertical direction D1, and a part of the etching stop layer 32 may be located under the silicon-rich interfacial layer in the vertical direction D1, but not limited thereto. In addition, a thickness of the silicon-rich interfacial layer (such as the interfacial layer F2 or the mixed interfacial layer 28M) may be less than the thickness of the silicon germanium cap layer 26, but not limited thereto.

To summarize the above descriptions, in the semiconductor structure and the manufacturing method thereof according to the present invention, the silicon cap layer may be formed on the silicon germanium epitaxial structure for forming the silicon-rich interfacial layer between the silicon germanium epitaxial structure and the oxide cap layer during the subsequent process of forming the oxide cap layer and/or after the oxide cap layer is formed. The performance of protecting the silicon germanium epitaxial structure may be enhanced accordingly for improving the related manufacturing yield and/or enhancing the operation performance of the related semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor structure, comprising:
providing a semiconductor substrate, wherein the semiconductor substrate comprises a fin-shaped structure;
forming a silicon germanium epitaxial structure on the fin-shaped structure;
forming a silicon cap layer on the silicon germanium epitaxial structure; and
forming an oxide cap layer on the silicon cap layer.

2. The manufacturing method of the semiconductor structure according to claim 1, wherein at least a part of the silicon cap layer is oxidized to be silicon oxide in an interfacial layer located between the oxide cap layer and the silicon germanium epitaxial structure by a process of forming the oxide cap layer.

3. The manufacturing method of the semiconductor structure according to claim 2, wherein the interfacial layer comprises a silicon germanium oxide layer.

4. The manufacturing method of the semiconductor structure according to claim 1, wherein the oxide cap layer is formed by an atomic layer deposition (ALD) process.

5. The manufacturing method of the semiconductor structure according to claim 1, wherein the oxide cap layer is an aluminum oxide layer.

6. The manufacturing method of the semiconductor structure according to claim 1, further comprising:
forming a silicon germanium cap layer on the silicon germanium epitaxial structure before the silicon cap layer is formed, wherein an atomic percent of germanium in the silicon germanium cap layer is lower than an atomic percent of germanium in the silicon germanium epitaxial structure.

7. The manufacturing method of the semiconductor structure according to claim 6, wherein an atomic percent of silicon in the silicon cap layer is higher than an atomic percent of silicon in the silicon germanium cap layer before the oxide cap layer is formed.

8. The manufacturing method of the semiconductor structure according to claim 1, further comprising:
forming a contact structure, wherein the contact structure is electrically connected with the silicon germanium epitaxial structure, and a part of the oxide cap layer is removed before the contact structure is formed.

9. The manufacturing method of the semiconductor structure according to claim 8, further comprising:
performing wet chemical treatments to the semiconductor substrate after the oxide cap layer is formed and before the part of the oxide cap layer is removed.

10. The manufacturing method of the semiconductor structure according to claim 9, wherein the wet chemical treatments comprise photoresist strip processes and wet cleaning processes.

11. The manufacturing method of the semiconductor structure according to claim 1, wherein a part of the silicon cap layer and a part of the oxide cap layer are formed on a sidewall of the silicon germanium epitaxial structure.

12. The manufacturing method of the semiconductor structure according to claim 1, wherein a part of the silicon cap layer and a part of the oxide cap layer are located under a sidewall of the silicon germanium epitaxial structure.

13. A semiconductor structure, comprising:
a semiconductor substrate comprising a fin-shaped structure;
a silicon germanium epitaxial structure disposed on the fin-shaped structure;
an oxide cap layer encompassing the silicon germanium epitaxial structure; and
a silicon-rich interfacial layer disposed between the silicon germanium epitaxial structure and the oxide cap layer.

14. The semiconductor structure according to claim 13, wherein the silicon-rich interfacial layer comprises a silicon germanium oxide layer, and an atomic percent of silicon in the silicon germanium oxide layer is greater than an atomic percent of germanium in the silicon germanium oxide layer.

15. The semiconductor structure according to claim 13, wherein the oxide cap layer is an aluminum oxide layer.

16. The semiconductor structure according to claim 13, further comprising:
a silicon germanium cap layer disposed on the silicon germanium epitaxial structure, wherein the silicon germanium cap layer is located between the silicon-rich interfacial layer and the silicon germanium epitaxial structure, and an atomic percent of germanium in the silicon germanium cap layer is lower than an atomic percent of germanium in the silicon germanium epitaxial structure.

17. The semiconductor structure according to claim 16, wherein a thickness of the silicon-rich interfacial layer is less than a thickness of the silicon germanium cap layer.

18. The semiconductor structure according to claim 13, wherein a part of the silicon-rich interfacial layer and a part of the oxide cap layer are located on a sidewall of the silicon germanium epitaxial structure.

19. The semiconductor structure according to claim 13, wherein a part of the silicon-rich interfacial layer and a part of the oxide cap layer are located under a sidewall of the silicon germanium epitaxial structure.

20. The semiconductor structure according to claim 13, further comprise:
an etching stop layer disposed on the oxide cap layer, wherein a part of the etching stop layer is located under the silicon-rich interfacial layer.
